(19) United States
(12) Patent Application Publication
(10) Pub. No.: US 2012/0275045 A1
(43) Pub. Date: Nov. 1, 2012

(54) BLUE PHOTORESIST AND COLOR FILTER SUBSTRATE AND DISPLAY DEVICE USING THE SAME

(75) Inventors: Kuei-Bai CHEN, Hsin-Chu (TW); Chien-Kai CHEN, Hsin-Chu (TW); Chen-Hsien LIAO, Hsin-Chu (TW); Chia-Hao LI, Hsin-Chu (TW)

(73) Assignee: AU OPTRONICS CORP., Hsinchu (TW)

(21) Appl. No.: 13/327,967

(22) Filed: Dec. 16, 2011

(30) Foreign Application Priority Data
Apr. 28, 2011 (TW) 100114956

(51) Int. Cl. G02B 5/22; G03F 7/027; G02B 5/23; G03F 7/004

(52) U.S. Cl. 359/891; 430/270.1; 430/281.1; 252/586

(57) ABSTRACT

A blue photoresist for a color filter substrate is provided. In the wavelength 380 nm to 580 nm, the half-width of the spectrum function of the blue photoresist is represented as Ha, the half-width of the color match function defined by CIE (Commission International de L'Eclairage) at 1931 is presented as Hb, and 3.7>Ha/Hb>1.91. Therefore, the light transmittance of the blue photoresist can be improved so that the efficiency utilizations of light of a color filter substrate and display device using the blue photoresist are provided.

### BACKGROUND

1. Technical Field

The present invention relates to a display device, and more particularly to a blue photoresist for a color filter substrate, and a color filter substrate and a display device using the blue photoresist.

2. Description of the Related Art

As flat panel display technology continues to develop and flat panel display devices have the advantages of light weight, small volume and saving electricity, the flat panel display devices become more and more popular. The common flat panel display devices include liquid crystal displays (LCDs), plasma display panels (PDPs), organic light emitting diode (OLED) displays, electrophoretic displays (EPD), and so on.

Among these display devices, most need to use color filter substrates to display color images. In order to make the chromatic performances of the images shown by the display devices to meet needs, a thickness of a blue photoresist film of a color filter substrate is usually increased, but this will result in a decrease in light transmission of the blue photoresist film, further result in that white spots shown by the display devices are yellowish white spots. Furthermore, height difference between the blue photoresist and other color photoresists will also cause adverse effects on the image display quality of the display device.

### BRIEF SUMMARY

Therefore, the object of the present invention is to provide a blue photoresist having improved light transmission without increasing thickness.

Another object of the present invention is to provide a color filter substrate, to enhance the light use efficiency of a display device.

A further object of the present invention is to provide a display device, to display images having good color performance and high-brightness.

The present invention provides a blue photoresist for a color filter substrate. In the wavelength 380 nm to 580 nm, the half-width of the spectrum function of the blue photoresist is represented as Ha, the half-width of the color match function Z defined by CIE (Commission International de L'Eclairage) is presented as Hb, and 3.7>Ha/Hb>1.91.

The present invention provides a color filter substrate, which includes a plurality of red photoresists, a plurality of green photoresists and a plurality of aforementioned blue photoresists. The red photoresist, the green photoresist and the blue photoresist are disposed on a substrate.

The present invention provides a display device, which includes a display panel and backlight module. The display panel includes an active element array substrate, the aforementioned color filter substrate and a display medium layer disposed between the active element array substrate and the color filter substrate. Further, the y-coordinate value of a standard light C defined by CIE on the chromaticity diagram defined by CIE at 1931 is represented as Cy, and the y-coordinate value of a light emitted after the standard light C transmitting through the color filter substrate on the chromaticity diagram defined by CIE at 1931 is represented as Wy. The backlight module includes at least one light emitting diode adopts to emit a light. The y-coordinate value of the light emitted from the at least one light emitting diode on the chromaticity diagram defined by CIE at 1931 is represented as Ly. Accordingly, the difference between Cy and Wy is approximate to the difference between Ly and Cy.

Because the blue photoresist of the invention has high light transmittance, compared with the typical technology, the overall light transmittance of the color filter substrate can be improved, thus making the display device of the invention can simultaneously have high brightness and good chromatic performance.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic cross-section of a color filter substrate in accordance with an embodiment of the invention;

FIG. 2 is a transmission spectrum function diagram of a blue photoresist, a red color matching function and a blue color matching function in accordance with an embodiment of the invention;

FIG. 3 is a schematic cross-section of a display device in accordance with an embodiment of the invention;

FIG. 4 is a schematic cross-section of a backlight module in accordance with another embodiment of the invention;

FIG. 5 is a schematic cross-section of a light emitting diode in accordance with an embodiment of the invention; and

FIG. 6 is a relationship graph between the luminances of the light emitting diode and y-coordinates on the chromaticity diagram of the light emitted from the light emitting diode.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

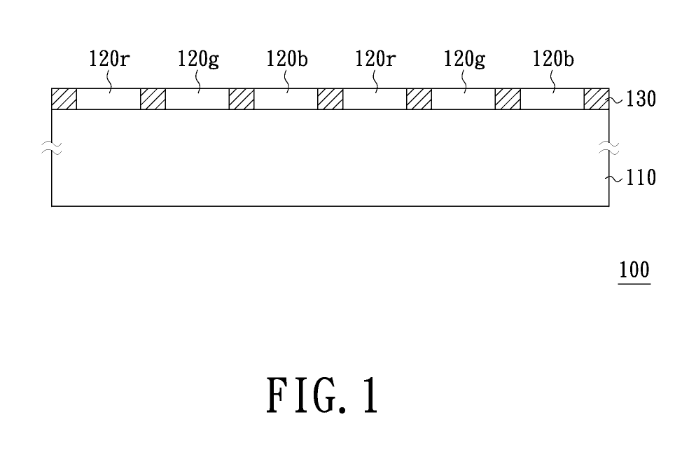

FIG. 1 is a schematic cross-section of a color filter substrate in accordance with an embodiment of the invention. Referring to FIG. 1, the color filter substrate 100 includes a substrate 110, a plurality of red photoresists 120r, a plurality of green photoresists 120g and a plurality of blue photoresists 120b, in which the red photoresists 120r, the green photoresists 120g and the blue photoresists 120b are disposed on the substrate 110. Furthermore, the color filter substrate 100 can further include a black matrix 130 which is used for shading. The black matrix 130 can be disposed on the substrate 110, and the red photoresists 120r, the green photoresists 120g and the blue photoresists 120b can be located in the areas defined by the black matrix 130.

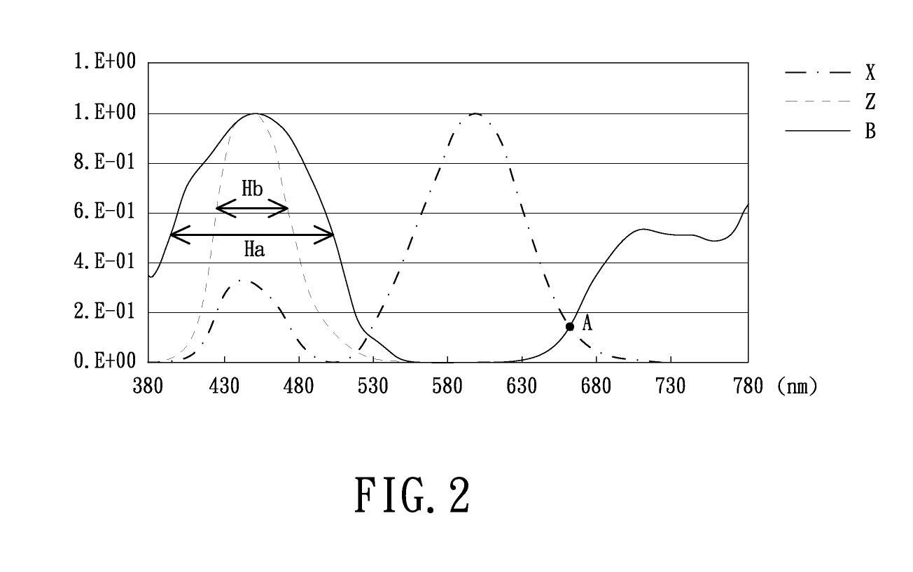

FIG. 2 is a transmission spectrum function diagram of a blue photoresist, a red color matching function (color match function X) and a blue color matching function (color match function Z) n accordance with an embodiment of the invention. Referring to FIG. 2, in order to improve light transmission of the blue photoresists 120b of the color filter substrate 100, the types of compositions and composition ratio of the types of compositions of each blue photoresist 120b are specially adjusted, so that in the wavelength 380 nm to 580 nm, the half-width of the spectrum function B of each blue photoresist 120b represented as Ha and the half-width of the color match function Z defined by CIE presented as Hb satisfy the following relationship: 3.7>Ha/Hb>1.91.

In particular, in the wavelength 630 nm to 780 nm, the spectrum function B of the blue photoresist 120b intersects with the color match function X at a point A, and the corresponding intensity of the spectrum function B of the blue photoresist 120b at the point A is 0.02 times as large as the intensity corresponding to a main peak point P of the color match function X.

Specifically, in order to make the blue photoresist 120b satisfy the above conditions, in this embodiment, each blue photoresist 120b includes at least one kind of blue pigment and at least one kind of blue dye. The materials of the blue pigment includes phthalocyanine, and the materials of the blue dye can include anthraquinone dye, azo dye, direct dye, acid dye or basic dye.

In particular, the corresponding intensity of the blue photoresist 120b at the point A where the spectrum function B of the blue photoresist 120b intersects with the color match function X, can be determined by adjustment of the proportion of the blue dye in the blue photoresist 120b. It should be noted that, the invention does not need to limit composition and proportion of the blue pigment and the blue dye of the blue photoresist 120b here, those familiar with this art can adjust the proportion according to the selected compositions of the blue pigment and the blue dye, to get the blue photoresist 120b which can satisfy the above conditions, and this is still within the scope of protection of the invention.

The following will list data to further compare the color filter substrate 100 with typical color filter substrates and the blue photoresist 120b with typical blue photoresist. It should be noted that, the data listed below is not intended to limit the invention.

In the following Table 1, x and y represent x-coordinate value and y-coordinate value on the chromaticity diagram defined by CIE (Commission International de L'Eclairage) at 1931 corresponding to a blue light emitted from the blue photoresist after a standard light C defined by CIE transmitting through the blue photoresist, Y represents the brightness of the blue light emitted from the blue photoresist after the standard light C transmitting through the blue photoresist.

TABLE 1

| | x | y | Y |
|---|---|---|---|
| typical blue photoresist | 0.155 | 0.043 | 1.50 |
| The blue photoresist 120b of this embodiment | 0.157 | 0.046 | 1.81 |

As can be seen from the Y values in Table 1, compared with the typical technology, the blue photoresist 120b of this embodiment can have higher light transmittance.

In the following Table 2, x and y represent x-coordinate value and y-coordinate value on the chromaticity diagram defined by CIE at 1931 corresponding to a white light emitted from color filter substrate after the standard light C defined by CIE transmitting through the color filter substrate, Y represents the brightness of the white light emitted from the color filter substrate after the standard light C transmitting through the color filter substrate.

TABLE 2

| | x | y | Y |
|---|---|---|---|
| typical color filter substrate | 0.269 | 0.274 | 5.95 |
| the color filter substrate 100 of this embodiment | 0.264 | 0.263 | 6.05 |

As can be seen from the Y values in Table 2, compared with the typical technology, the color filter substrate 100 of this embodiment can raise the overall transmittance of the standard light C about 2%.

Further, as can be seen from Table 2, compared with the typical technology, the y-coordinate value on the chromaticity diagram corresponding to the white light, which is emitted from the color filter substrate 100 after the standard light C transmitting through the color filter substrate 100 of this embodiment, shifts from 0.274 to 0.263, thus making the white light emitted from the color filter substrate 100 slightly bluish. In order to improve the chromatic performance of a display device using the color filter substrate 100, a backlight module is used in the display device to carry out chromatic compensation, and illustrative embodiments are given below.

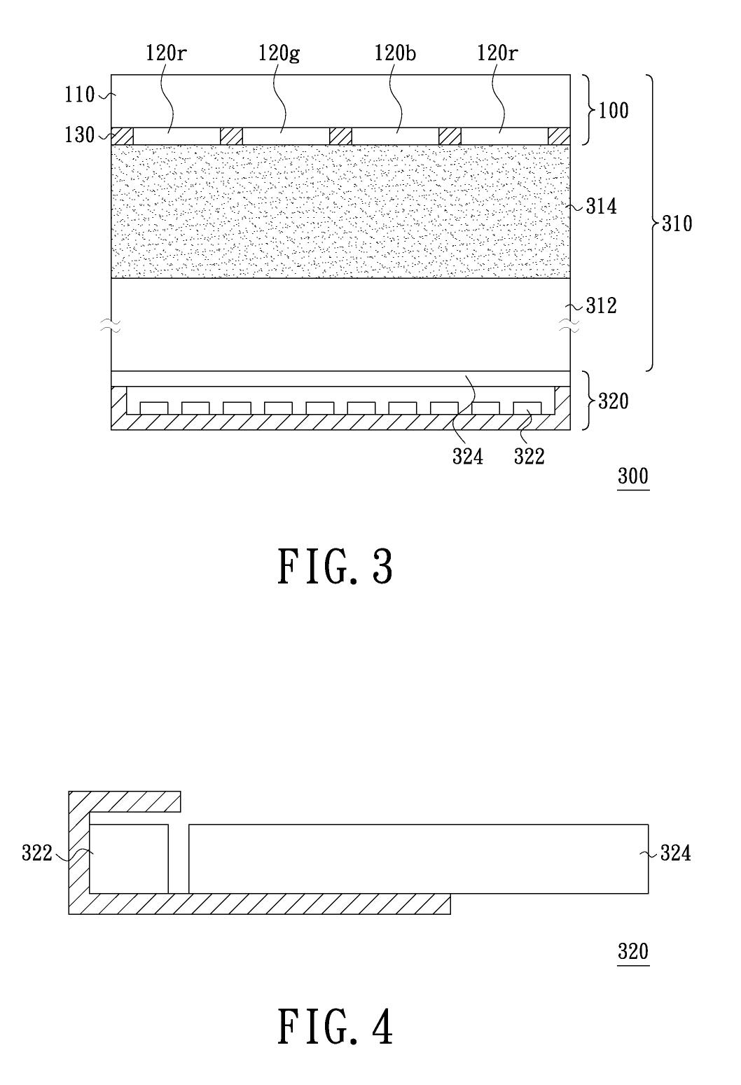

FIG. 3 is a schematic cross-section of a display device in accordance with an embodiment of the invention. Referring to FIG. 3, a display device 300 includes a display panel 310 and a backlight module 320. The display panel 310 is disposed above the backlight module 320 and includes the color filter substrate 100, an active element array substrate 312 and a display medium layer 314. The active element array substrate 312, for example, can be a thin film transistor array substrate, and the color filter substrate 100 is disposed above the active element array substrate 312. The composition and properties of the color filter substrate 100 is described above, and not repeated here. The display medium layer 314 is disposed between the active element array substrate 312 and the color filter substrate 100. In this embodiment, the display medium layer 314 for example, can be a liquid crystal layer.

The backlight module 320 includes at least one light emitting diode (LED) 322 and at least one optical component 324. In this embodiment, the backlight module 320 includes a plurality of light emitting diodes 322. For example, the light emitting diodes 322 are arranged in an array. For example, the backlight module 320 can be a direct type backlight module. That is, the optical component 324 can be composed of multiple optical films, and is disposed above the light emitting diodes 322. However, the backlight module 320 is not limited hereto, in some embodiments, the backlight module 320 can be a edge backlight module, as shown in FIG. 4, in that case, the optical component 324 is a light guide plate.

Because the blue photoresist 120b of the color filter substrate 100 has high light transmittance, there is a difference Δy between the y-coordinate values Wy and Cy in the chromaticity diagram. The y-coordinate value Wy corresponds to the light emitted from the color filter substrate 100 after the standard light C transmitting through the color filter substrate 100, and the y-coordinate value Cy corresponds to the standard light C. Specifically, the y-coordinate value Wy is on the left of the y-coordinate value Cy, and there is an interval Δy between the y-coordinate value Wy and y-coordinate value Cy. A difference between the y-coordinate value Ly and the y-coordinate value Cy on the chromaticity diagram is approximate to Δy, and the y-coordinate value Ly is on the right of the y-coordinate value Cy. The y-coordinate value Ly corresponds to the light emitted by the light emitting diodes 322 of this embodiment. Thus, the y-coordinate value on the chromaticity diagram corresponding to the light which is emitted from the light emitting diodes 322 and transmitting through the color filter substrate 100 is approximate to the y-coordinate value Cy on the chromaticity diagram corresponding to the standard light C.

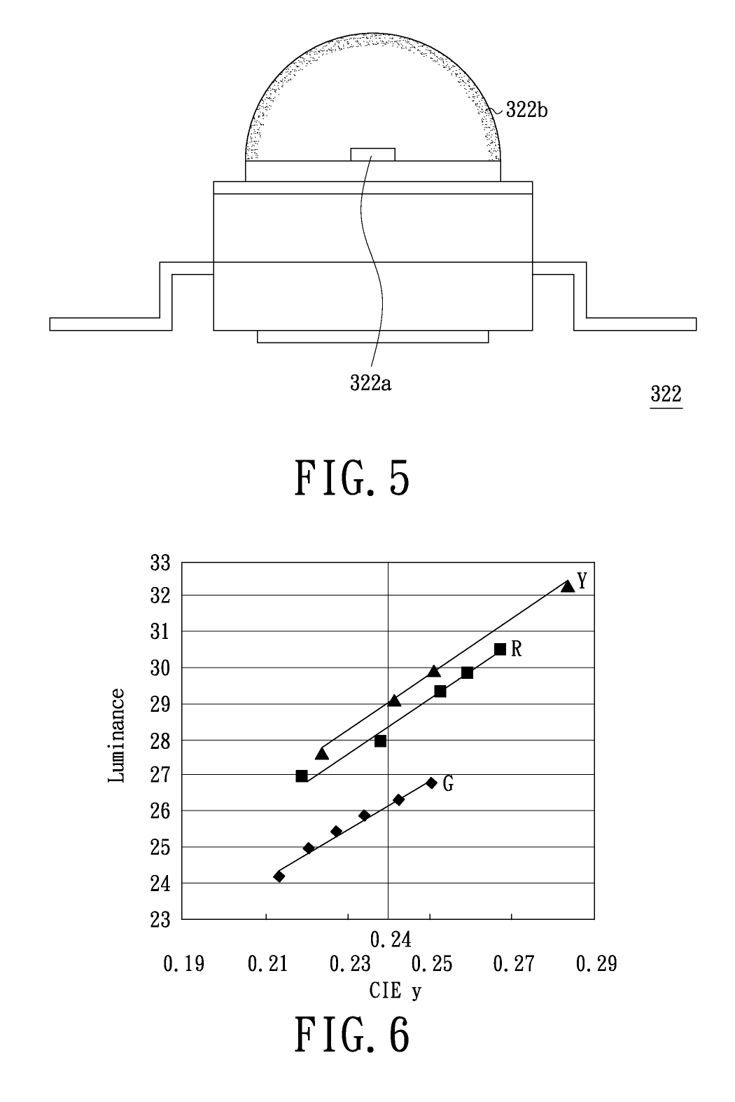

In details, as shown in FIG. 5, the light emitting diodes 322 of this embodiment, for example, includes a blue light source 322a and phosphor 322b. The blue light source 322a is a light emitting diode chip which can emit blue light. When the blue light is irradiated on the phosphor 322b, the phosphor 322b can be excited to emit excitation light which is mixed with the blue light to form the light emitted from the light emitting diodes 322. In this embodiment, the phosphor 322b can be fluorescent material which uses silicate, nitride or (Y3Al5O12):Ce as base materials. That is, the light emitting diodes 322 of this embodiment, for example, can be YAG light emitting diodes, RG light emitting diodes, or YR light emitting diodes.

For illustration, the invention is only in FIG. 5 showing the structure and style of common light emitting diodes, but it is not used to limit the invention. Those familiar with this art can change the structure and style of the light emitting diodes, and this is still within the scope of protection of the invention.

FIG. 6 is a relationship graph between the luminance of the light emitting diode and the y-coordinates on the chromaticity diagram of the light emitted from the light emitting diode, in which curve G represents RG light emitting diode, curve R represents YR light emitting diode and curve Y represents YAG light emitting diode. As shown in FIG. 6, the luminances of the light emitting diodes are proportional to the y-coordinates on the chromaticity diagram of the light emitted from the light emitting diodes. That is, the greater the y-coordinates on the chromaticity diagram of the light emitted from the light emitting diode 322 selected in this embodiment, the higher the luminous efficiency thereof.

Using the data in Table 2 as an example, if a y-coordinate on the chromaticity diagram of a white point of an image shown by the display device 300 is required to go right from 0.263 to 0.274, in this situation, a light emitting diode which emitting a light with a y-coordinate on the chromaticity diagram shifting right to 0.011 compared with the light emitting diode in used in typical technology can be selected to carry out chromatic compensation for color filter substrate 100. In this situation, the luminous efficiency of the light emitting diode 322 used in this embodiment is at least 5% greater than that of light emitting diodes used in typical technology. Taking into account light transmittance improved by the color filter substrate 100 and luminous efficiency improved by the backlight module, it can be learned, compared with the typical technology, the light utilization efficiency of the display device 300 can be enhanced by 7%.

In summary, in the invention, in the wavelength 380 nm to 580 nm, the half-width of the spectrum function of the blue photoresist is represented as Ha, the half-width of the color match function Z defined by CIE is presented as Hb, and 3.7>Ha/Hb>1.91. Therefore, the overall light transmittance of the blue photoresist and the color filter substrate can be improved. Further, the display device of the invention can use the light source of the backlight module to carry out color compensation for the color filter substrate, so that the color quality of the image shown by the display device can be improved.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A blue photoresist for a color filter substrate, wherein in the wavelength 380 nm to 580 nm, the half-width of the spectrum function of the blue photoresist represented as Ha and the half-width of the color match function defined by CIE (Commission International de L'Eclairage) presented as Hb satisfy the following relationship: 3.7>Ha/Hb>1.91.

2. The blue photoresist according to claim 1, wherein in the wavelength 630 nm to 780 nm, the spectrum function of the blue photoresist intersects with a red color matching function defined by CIE at a point A in a function-light intensity diagram, and corresponding intensity of the spectrum function of the blue photoresist at the point A is 0.02 times as large as an intensity corresponding to a main peak point of the red color matching function.

3. The blue photoresist according to claim 1, comprising a blue pigment and a blue dye.

4. The blue photoresist according to claim 3, wherein the material of the blue pigment comprises phthalocyanine.

5. The blue photoresist according to claim 3, wherein the materials of the blue dye comprise anthraquinone dye, azo dye, direct dye, acid dye or basic dye.

6. A color filter substrate comprising:
a plurality of red photoresists;
a plurality of green photoresists; and
a plurality of blue photoresists disposed on a substrate with the red photoresists and the green photoresists;
wherein in the wavelength 380 nm to 580 nm, the half-width of the spectrum function of the blue photoresist represented as Ha and the half-width of the color match function defined by CIE (Commission International de L'Eclairage) presented as Hb satisfy the following relationship: 3.7>Ha/Hb>1.91.

7. The color filter substrate according to claim 6, wherein in the wavelength 630 nm to 780 nm, the spectrum function of the blue photoresist intersects with a red color matching function defined by CIE at a point A in a function-light intensity diagram, and corresponding intensity of the spectrum function B of the blue photoresist at the point A is 0.02 times as large as an intensity corresponding to a main peak point of the red color matching function.

8. The color filter substrate according to claim 6, comprising a blue pigment and a blue dye.

9. The color filter substrate according to claim 8, wherein the material of the blue pigment comprises phthalocyanine.

10. The color filter substrate according to claim 8, wherein the materials of the blue dye comprise anthraquinone dye, azo dye, direct dye, acid dye or basic dye.

11. A display device comprising:
a display panel comprising:
an active element array substrate;
a color filter substrate disposed above the active element array substrate, comprising a plurality of red photoresists, a plurality of green photoresists, and a plurality of blue photoresists disposed on a substrate with the red photoresists and the green photoresists, wherein in the wavelength 380 nm to 580 nm, the half-width of the spectrum function of each blue photoresist represented as Ha and the half-width of the color match function defined by CIE (Commission International de L'Eclairage) represented as Hb satisfying the following relationship: 3.7>Ha/Hb>1.91;
wherein Cy representing the y-coordinate value of a standard light C defined by CIE on the chromaticity diagram defined by CIE at 1931, and Wy representing the coordinate value of a light emitted after the standard light C transmitting through the color filter substrate on the chromaticity diagram defined by CIE at 1931;
a display medium layer disposed between the active element array substrate and the color filter substrate; and
a backlight module comprising at least one light emitting diode adopt to emit a light, wherein Ly representing the y-coordinate value of the light emitted from the at least one light emitting diode on the chromaticity diagram defined by CIE at 1931, a difference between Cy and Wy is approximate to a difference between Ly and Cy.

12. The display device according to claim 11, wherein in the wavelength 630 nm to 780 nm, the spectrum function of the blue photoresist intersects with a red color matching function defined by CIE at a point A in a function-light intensity diagram, and corresponding intensity of the spectrum function f the blue photoresist at the point A is 0.02 times as large as an intensity corresponding to a main peak point of the red color matching function.

13. The display device according to claim 11, wherein the color filter substrate comprises a blue pigment and a blue dye.

14. The display device according to claim 13, wherein the material of the blue pigment comprises phthalocyanine.

15. The display device according to claim 13, wherein the materials of the blue dye can comprise anthraquinone dye, azo dye, direct dye, acid dye or basic dye.

16. The display device according to claim 11, wherein the at least one light emitting diode comprises a blue light source using for emitting a blue light and a phosphor using for being excited to emit an excitation light through being irradiated by the blue light, the excitation light mixed with the blue light to form the light emitted from the at least one light emitting diode.

17. The display device according to claim 16, wherein the phosphor comprises fluorescent material which uses silicate, nitride or (Y3Al5O12):Ce as base materials.
